(19) United States
(12) Patent Application Publication
(10) Pub. No.: US 2022/0011058 A1
(43) Pub. Date: Jan. 13, 2022

(54) COOLING UNIT

(71) Applicant: Toyota Jidosha Kabushiki Kaisha, Toyota-shi Aichi-ken (JP)

(72) Inventor: Toshinari Ueyama, Toyota-shi (JP)

(73) Assignee: Toyota Jidosha Kabushiki Kaisha, Toyota-shi Aichi-ken (JP)

(21) Appl. No.: 17/369,170

(22) Filed: Jul. 7, 2021

(30) Foreign Application Priority Data
Jul. 10, 2020 (JP) 2020-119352

(51) Int. Cl. F28F 1/40

(52) U.S. Cl. CPC F28F 1/40

(57) ABSTRACT

A cooling unit includes a member-to-be-cooled and a duct. The member-to-be-cooled includes a plurality of cooling fins. The duct is fixed to the member-to-be-cooled and has an outlet. The duct and the member-to-be-cooled define a cooling passage that conveys a gas to around the cooling fins and discharges the gas having passed the cooling fins through the outlet. The cooling passage includes a bend between the cooling fins and the outlet. The duct includes an outer corner that constitutes a partition wall on an outer peripheral side of the bend and the duct has a drain hole that is bored through the outer corner.

### CROSS-REFERENCE TO RELATED APPLICATION

This application claims priority to Japanese Patent Application No. 2020-119352 filed on Jul. 10, 2020, incorporated herein by reference in its entirety.

### BACKGROUND

### 1. Technical Field

A technique to be disclosed in this specification relates to a cooling unit.

### 2. Description of Related Art

Japanese Patent Application Publication No. 2008-213668 discloses an air intake duct of an automobile engine.

### SUMMARY

To cool a member-to-be-cooled having a plurality of cooling fins, a duct can be mounted to the member-to-be-cooled. In a cooling unit in which a duct is mounted on the member-to-be-cooled, a cooling passage that conveys a gas to around the cooling fins can be formed by a space surrounded by the duct and the member-to-be-cooled. Inside this type of cooling unit, dew condensation can occur. The present disclosure proposes a cooling unit that can appropriately discharge water produced by dew condensation to the outside.

An aspect of the present disclosure relates to a cooling unit that includes a member-to-be-cooled, and a duct. The member-to-be-cooled includes a plurality of cooling fins. The duct is fixed to the member-to-be-cooled and has an outlet. The duct and the member-to-be-cooled define a cooling passage that conveys a gas to around the plurality of cooling fins and discharges the gas having passed the plurality of cooling fins through the outlet. The cooling passage includes a bend between the plurality of cooling fins and the outlet. The duct includes an outer corner that constitutes a partition wall on the outer peripheral side of the bend, and the duct has a drain hole that is bored through the outer corner.

In this cooling unit, the gas having passed the cooling fins passes through the bend and is discharged to the outside of the cooling unit through the outlet. When water is produced by dew condensation inside the cooling unit, this water is forced to flow along an inner wall of the cooling passage by an air pressure. At the bend, the gas flow changes, generating a high air pressure toward the outer side of the curve (i.e., toward the outer corner). Therefore, the water is likely to flow toward the outer corner. Since the drain hole is provided at the outer corner, the water is likely to flow toward the drain hole. When the water reaches the drain hole, the water is discharged to the outside of the cooling unit through the drain hole by an air pressure. Thus, this cooling unit can appropriately discharge water produced by dew condensation to the outside of the cooling unit.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a plan view of a cooling unit;

FIG. 2 is a sectional view taken along line II-II of FIG. 1;

FIG. 3 is a sectional view taken along line of FIG. 1; and

FIG. 4 is a plan view with a duct shown in section.

### DETAILED DESCRIPTION OF EMBODIMENTS

In one example of the cooling unit disclosed in this specification, the gas may flow toward a lower side in the cooling passage on an upstream side of the bend, and the gas may flow toward an upper side in the cooling passage on a downstream side of the bend.

The gas flows toward the lower side means that the gas flow direction includes at least a downward vector component. Therefore, the gas may flow vertically downward or may flow obliquely downward. That the gas flows toward the upper side means that the gas flow direction includes at least an upward vector component. Therefore, the gas may flow vertically upward or may flow obliquely upward.

In this configuration, the outer corner is located at a lower part of the bend, so that water is forced to flow to the outer corner (i.e., the drain hole) not only by the air pressure but also by gravity. Therefore, the water can be more appropriately discharged to the outside of the cooling unit.

In one example of the cooling unit disclosed in this specification, the drain hole may extend downward from the cooling passage.

The drain hole may extend vertically downward from the cooling passage or may extend obliquely downward from the cooling passage.

In this configuration, the water having flowed into the drain hole is likely to be forced to flow to the outside by gravity. Therefore, the water can be more appropriately discharged to the outside of the cooling unit.

In one example of the cooling unit disclosed in this specification, the bend may have a valley that extends linearly, and the valley may slope so as to descend toward the drain hole.

In this configuration, the water is more likely to flow into the drain hole.

In one example of the cooling unit disclosed in this specification, a flow direction of the gas may change by 90° or more at the bend.

In this configuration, an air pressure is more likely to be exerted on the outer corner, so that the water can be more appropriately discharged to the outside of the cooling unit.

In one example of the cooling unit disclosed in this specification, the area of the drain hole may be not larger than one hundredth of the area of the outlet.

In this configuration, gas leakage through the drain hole can be minimized.

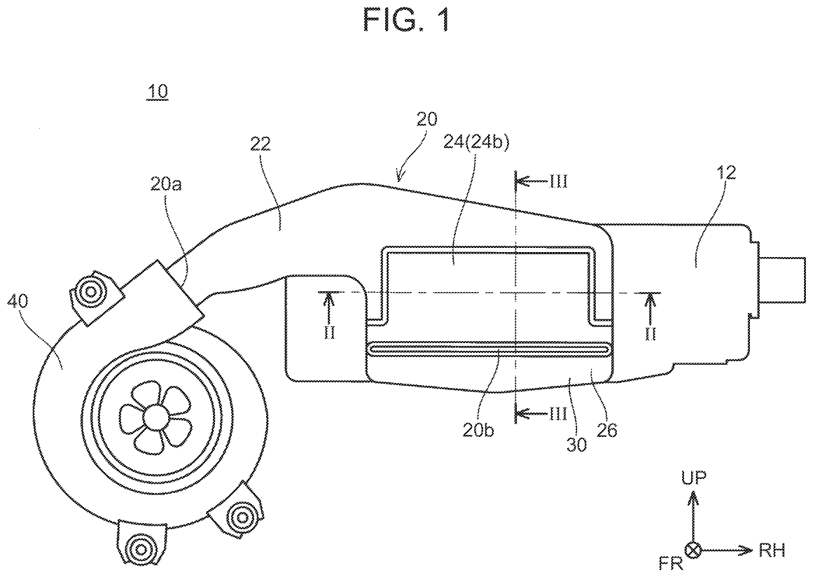

A cooling unit 10 shown in FIG. 1 is installed in a vehicle (in this embodiment, an electric vehicle). In the drawings including FIG. 1, arrows UP, FR, and RH indicate a vehicle upward direction, a vehicle frontward direction (advancing direction), and a vehicle rightward direction, respectively. The cooling unit 10 has a DC-DC converter 12, a duct 20, and a blower 40. The DC-DC converter 12 supplies electricity to a motor of the vehicle. The duct 20 is mounted on the DC-DC converter 12. The blower 40 sends air into the duct 20. The air flowing through the duct 20 cools the DC-DC converter 12. The DC-DC converter 12 is an example of a member-to-be-cooled.

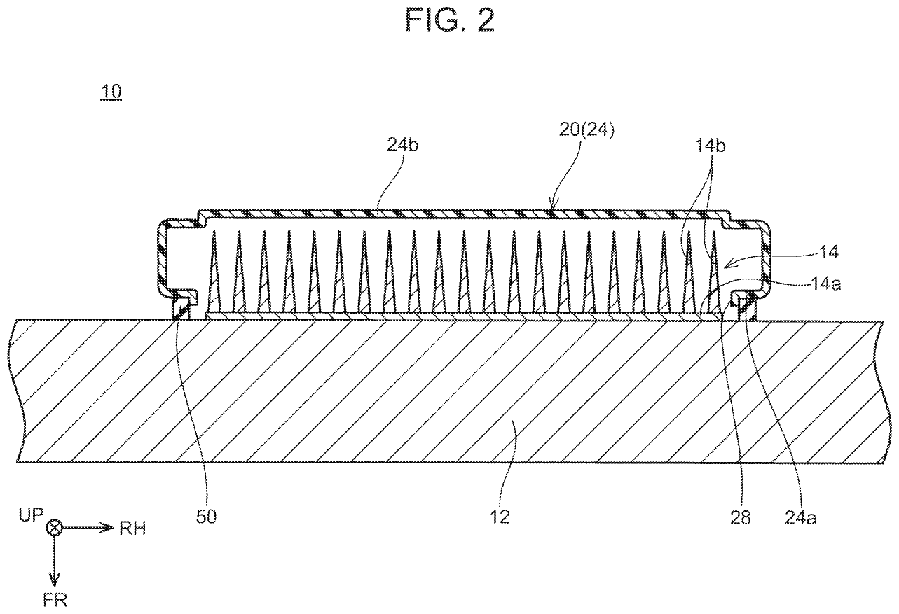

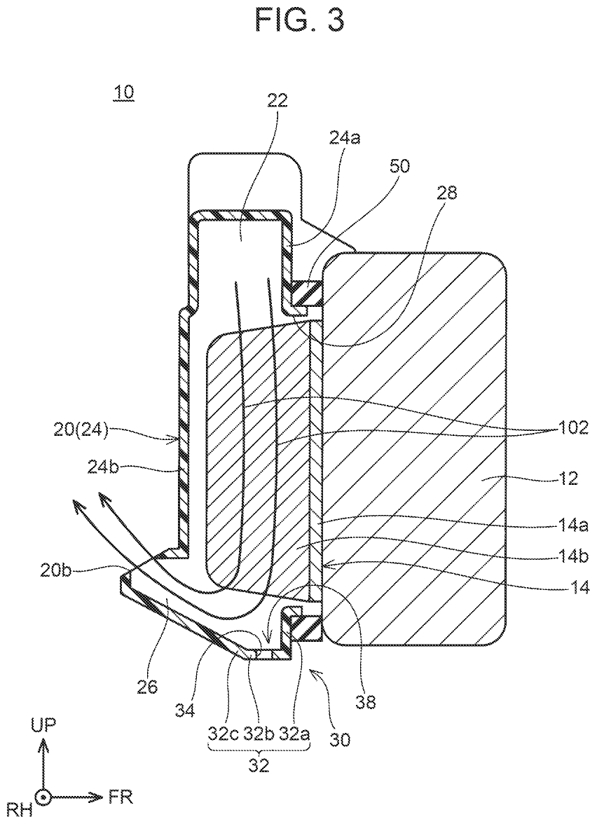

As shown in FIG. 2 and FIG. 3, the DC-DC converter 12 has a heatsink 14. The heatsink 14 is provided on a rear-side surface of the DC-DC converter 12. The heatsink 14 dissipates heat produced inside the DC-DC converter 12. The heatsink 14 has a baseplate 14a and a plurality of cooling fins 14b. The cooling fins 14b are erected on the baseplate 14a. The cooling fins 14b protrude from the baseplate 14a toward a rear side. The cooling fins 14b extend linearly along an up-down direction.

As shown in FIG. 1, the duct 20 is a tubular resin part extending from an inlet 20a to an outlet 20b. The duct 20 has an upstream part 22, a main part 24, and a downstream part 26. The main part 24 has a box shape. The upstream part 22 connects the inlet 20a and the main part 24 to each other. The downstream part 26 connects the main part 24 and the outlet 20b to each other. As shown in FIG. 2 to FIG. 4, a rectangular through-hole 28 is provided in a front-side partition wall 24a of the main part 24. The duct 20 is fixed to the DC-DC converter 12 with the cooling fins 14b inserted in the through-hole 28. Thus, the cooling fins 14b are housed in the box-shaped main part 24. As shown in FIG. 2 and FIG. 3, a rear-side partition wall 24b of the main part 24 faces tips of the cooling fins 14b. A packing 50 is provided at a joint between the duct 20 and the DC-DC converter 12. The packing 50 seals the joint between the duct 20 and the DC-DC converter 12. The packing 50 prevents air leakage from the joint.

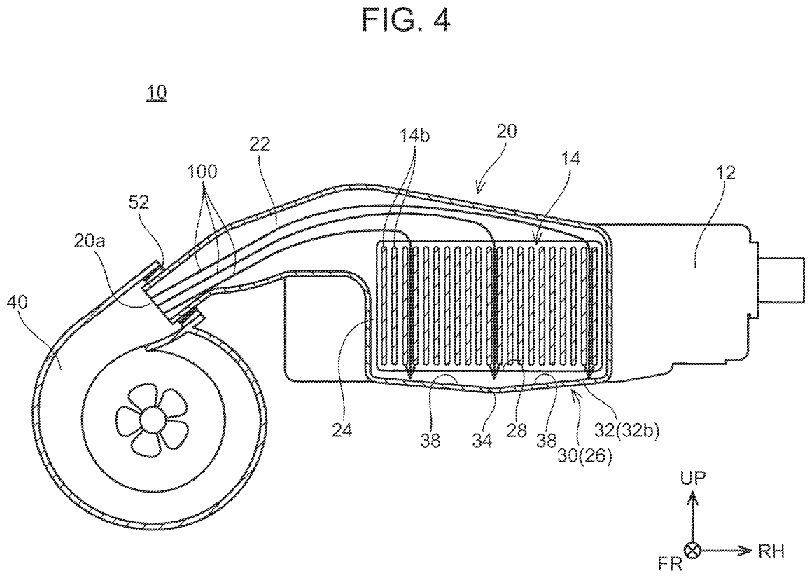

As shown in FIG. 1 and FIG. 4, the blower 40 is connected to the inlet 20a of the duct 20. The blower 40 is an electric blower and sends air through the inlet 20a of the duct 20. A packing 52 is provided at a joint between the duct 20 and the blower 40. The packing 52 seals the joint between the duct 20 and the blower 40. The packing 52 prevents air leakage from the joint.

When the blower 40 is activated, air is sent from the blower 40 into the upstream part 22 of the duct 20, as indicated by arrows 100 in FIG. 4. The air flowing through the upstream part 22 flows from an upper side to the inside of the main part 24, as indicated by arrows 100, 102 in FIG. 3 and FIG. 4. In the main part 24, an air flow passage is formed by a space surrounded by the duct 20 and the heatsink 14. In the main part 24, the air flows from top to bottom. When the air flows through the main part 24, the cooling fins 14b are cooled through heat exchange between the air and the cooling fins 14b. Thus, the DC-DC converter 12 is cooled inside the main part 24. As described above, the cooling fins 14b extend linearly along the up-down direction. In the main part 24, the air flows along the extension direction of the cooling fins 14b (up-down direction). In the main part 24, therefore, the air is less likely to stagnate and the cooling fins 14b are efficiently cooled by the air. As indicated by arrows 102 in FIG. 3, the air having passed through the main part 24 passes through the downstream part 26 and is discharged to the outside through the outlet 20b. Thus, a space surrounded by the duct 20 and the DC-DC converter 12 forms a cooling passage that conveys air for cooling the cooling fins 14b.

As indicated by arrows 102 in FIG. 3, the cooling passage (i.e., the air flow direction) bends on a lower side of the cooling fins 14b. This part of the cooling passage will be hereinafter referred to as a bend 30. The bend 30 is provided between the main part 24 (i.e., the cooling fins 14b) and the outlet 20b. On an upstream side of the bend 30 (i.e., in the main part 24), air flows from the upper side toward the lower side. At the bend 30, the air flow direction changes by 90° or more. On a downstream side of the bend 30 (i.e., near the outlet 20b), the air flows obliquely upward.

As shown in FIG. 4, the cooling fins 14b are provided in the main part 24 at intervals in a vehicle width direction. The bend 30 is provided under the main part 24, along an entire area of the main part 24 in the vehicle width direction. As shown in FIG. 1, the outlet 20b is elongated in the vehicle width direction. The outlet 20b is disposed at a higher level than a lowermost part of the bend 30. As indicated by arrows 100 in FIG. 4, the air flows from the upper side toward the lower side in the entire area of the main part 24 in the vehicle width direction (i.e., around the cooling fins 14b). Thus, in an entire area of the bend 30 in the vehicle width direction, air flows into the bend 30 from the upper side. At the bend 30, in the entire area thereof in the vehicle width direction, the airflow changes its direction to an obliquely upward direction, as indicated by arrows 102 in FIG. 3. Therefore, the air is discharged obliquely upward in an entire area of the outlet 20b in the vehicle width direction.

Reference sign 32 indicated in FIG. 3 denotes an outer corner that forms one of partition walls of the duct 20 on an outer peripheral side of the bend 30. The outer corner 32 has a first part 32a extending downward from the main part 24, a third part 32c extending obliquely upward toward the outlet 20b, and a second part 32b connecting the first part 32a and the third part 32c to each other. In the section shown in FIG. 3 (a vertical section along a vehicle front-rear direction), an inner surface of the second part 32b constitutes a valley 38 that forms a lowermost part (a part located on a lowermost side) of the cooling passage between the main part 24 and the outlet 20b. As shown in FIG. 4, the valley 38 extends linearly along the vehicle width direction. The second part 32b (i.e., the valley 38) slopes so as to shift toward the lower side as it extends toward the center of the main part 24 in the vehicle width direction. At a lowermost portion of the second part 32b (i.e., the center thereof in the vehicle width direction), a drain hole 34 bored through the second part 32b is provided. Thus, as shown in FIG. 4, the valley 38 slopes so as to descend toward the drain hole 34. The drain hole 34 extends downward from the valley 38 (an upper surface of the second part 32b). The diameter of the drain hole 34 is about 3 mm, and the area of the drain hole 34 is not larger than one hundredth of the area of the outlet 20b.

Inside the cooling unit 10, water (water droplets) can be produced by dew condensation. Water droplets can form, for example, on an inner side of the main part 24 (on the cooling fins 14b and an inner surface of the duct 20 around the cooling fins 14b). When water is produced by dew condensation inside the main part 24, this water flows down an inner surface of the main part 24 due to the airflow and gravity. Thus, the water flows from the main part 24 into the bend 30. At the bend 30, the downward airflow (i.e., the airflow toward the outer corner 32) changes its direction to an obliquely upward direction (a direction toward the outlet 20b). As a result, a high air pressure toward the outer corner 32 is generated at the bend 30. In particular, the airflow changes by 90° or more at the bend 30, thus generating a high air pressure toward the outer corner 32. The water is forced to flow to the outer corner 32 by this air pressure. The water is forced to flow to the outer corner 32 also by gravity. When the water lands on the valley 38 of the outer corner 32, the water is forced to flow along the valley 38 shown in FIG. 4 toward the center of the valley 38 (i.e., the drain hole 34) by the air pressure and gravity. When the water reaches the drain hole 34, the water is moved downward through the drain hole 34 and discharged to the outside of the cooling unit 10 by the air pressure and gravity.

As has been described above, the cooling unit 10 of the embodiment can appropriately discharge water produced inside the cooling unit 10 to the outside of the cooling unit 10 through the drain hole 34. Thus, accumulation of water inside the cooling unit 10 can be prevented. In the cooling unit 10, the area of the drain hole 34 is not larger than one hundredth of the area of the outlet 20b. Therefore, the amount of air leaking through the drain hole 34 is extremely small compared with the amount of air discharged through the outlet 20b. Thus, a situation where a large amount of high-temperature air is discharged to under the cooling unit 10 can be prevented.

While the embodiment has been described in detail above, this embodiment is merely an example and does not limit the scope of the claims. The technique described in the claims includes various modifications and changes made to the specific examples shown above. The technical elements illustrated in this specification or the drawings exhibit their technical usefulness independently or in various combinations, and the combinations are not limited to those described in the claims as filed. In addition, the technique illustrated in this specification or the drawings can achieve more than one purpose at the same time, and achieving one of the purposes itself proves its technical usefulness.

What is claimed is:

1. A cooling unit comprising:
a member-to-be-cooled including a plurality of cooling fins; and
a duct fixed to the member-to-be-cooled and having an outlet, wherein
the duct and the member-to-be-cooled defining a cooling passage that conveys a gas to around the plurality of cooling fins and discharges the gas having passed the plurality of cooling fins through the outlet,
the cooling passage includes a bend between the plurality of cooling fins and the outlet of the duct, and
the duct includes an outer corner that constitutes a partition wall on an outer peripheral side of the bend, and the duct has a drain hole that is bored through the outer corner.

2. The cooling unit according to claim 1, wherein:
the gas flows toward a lower side in the cooling passage on an upstream side of the bend; and
the gas flows toward an upper side in the cooling passage on a downstream side of the bend.

3. The cooling unit according to claim 2, wherein the drain hole extends downward from the cooling passage.

4. The cooling unit according to claim 2, wherein:
the bend has a valley that extends linearly; and
the valley slopes so as to descend toward the drain hole.

5. The cooling unit according to claim 1, wherein a flow direction of the gas changes by 90° or more at the bend.

6. The cooling unit according to claim 1, wherein an area of the drain hole is not larger than one hundredth of an area of the outlet of the duct.
